(19) United States
(12) Patent Application Publication
(10) Pub. No.: US 2017/0085229 A1
(43) Pub. Date: Mar. 23, 2017

(54) Semiconductor Device and Method of Making a Semiconductor Device

(71) Applicant: Ampleon Netherlands B.V., Nijmegen (NL)

(72) Inventor: Johannes Adrianus Maria De Boet, Nijmegen (NL)

(21) Appl. No.: 15/267,962

(22) Filed: Sep. 16, 2016

(30) Foreign Application Priority Data
Sep. 18, 2015 (EP) 15185954.3

(51) Int. Cl. H03F 1/30; H01L 29/10; H01L 29/08; H03F 3/24; H01L 29/66; H01L 21/265; H01L 21/324; H03F 3/195; H01L 29/78; H01L 27/092

(52) U.S. Cl. CPC H03F 1/301; H01L 29/7816; H01L 29/1095; H01L 29/0882; H01L 29/0865; H01L 27/092; H01L 29/66681; H01L 21/26513; H01L 21/324; H03F 3/195; H03F 3/245; H03F 2200/451

(57) ABSTRACT

A semiconductor device and a method of making the same. The device includes a semiconductor substrate having a major surface. the device also includes a gate located on the major surface. The device further includes a drain region having a first conductivity type. The device also includes a source region having the first conductivity type, wherein the source region is located within a region having a second conductivity type. The device further includes a channel region comprised of a part of the region having the second conductivity type that is located beneath the gate. The drain region extends laterally away from the gate along the major surface of the substrate. The drain also extends beneath the gate, the source region and the region having the second conductivity type to isolate the source region and the region having the second conductivity type from an underlying region of the substrate.

### CROSS-REFERENCE TO RELATED APPLICATIONS

This application claims priority to European Patent Application No. 15185954.3 filed on Sep. 18, 2015, the contents of which are incorporated entirely herein by reference.

### FIELD

The present specification relates to a semiconductor device and to a method of making a semiconductor device.

### BACKGROUND

RF power amplifiers are key components in base stations for personal communication systems (e.g. GSM, EDGE, W-CDMA). RF Laterally Diffused Metal Oxide Semiconductor (RF-LDMOS) transistors are a common choice of technology for power amplifiers of this kind.

In a power amplifier, the DC biasing point is a critical parameter governing performance. The optimum DC biasing point of an RF-LDMOS transistor depends on factors such as temperature and manufacturing process variations. A biasing circuit including a LDMOS transistor may be used to apply the DC bias. The biasing circuit may be integrated in the same semiconductor die as the RF-LDMOS transistor, so that the biasing circuit may compensate for temperature effects. A small reference LDMOS transistor, also provided in the same die, may be used to compensate for the manufacturing process variations.

### SUMMARY OF THE DISCLOSURE

Aspects of this disclosure are set out in the accompanying independent and dependent claims. Combinations of features from the dependent claims may be combined with features of the independent claims as appropriate and not merely as explicitly set out in the claims.

According to an aspect of this disclosure, there is provided a semiconductor device comprising:

a semiconductor substrate having a major surface;

a gate located on the major surface;

a drain region having a first conductivity type;

a source region having the first conductivity type, wherein the source region is located within a region having a second conductivity type;

a channel region comprised of a part of said region having the second conductivity type that is located beneath the gate, and

wherein the drain region extends laterally away from the gate along the major surface of the substrate and wherein the drain also extends beneath the gate, the source region and the region having the second conductivity type to isolate the source region and the region having the second conductivity type from an underlying region of the substrate.

According to another aspect of this disclosure, there is provided a method of making a semiconductor device, the method comprising:

providing a semiconductor substrate having a major surface;

forming a gate on the major surface;

forming a drain region having a first conductivity type;

forming a source region having the first conductivity type, wherein the source region is located within a region having a second conductivity type, and wherein a part of said region having the second conductivity type that is located beneath the gate forms a channel region of the device, and

wherein the drain region extends laterally away from the gate along the major surface of the substrate and wherein the drain also extends beneath the gate, the source region and the region having the second conductivity type to isolate the source region and the region having the second conductivity type from an underlying region of the substrate.

The drain region having the first conductivity type extending beneath the region having the second conductivity type may allow the source region of the device to be isolated from the underlying region of the substrate whereby, during use, different voltages may be applied to the source and the substrate. This may allow the device to be operated with a source voltage that is higher than the voltage applied to the substrate (a so called “source-high” device).

A method for making the device may include implanting ions through the major surface of the substrate for forming the drain region and then heating the substrate to diffuse the implanted ions to form the drain region, wherein the drain region extends beneath the gate, the source region and the region having the second conductivity type. When formed in this way, a part of the drain region located beneath the gate may extend to a depth beneath the major surface that is shallower than a depth to which a part of the drain region not located beneath the gate extends. The relative shallowness of the part of the drain region located beneath the gate may be formed by shadowing of this part of the device by the gate during ion implantation. It has been determined that the relative shallowness of the part of the drain region located beneath the gate may improve the field distribution within the device, allowing for a higher maximum drain to source voltage BV_{dss} owing to the reduced surface field (RESURF) action in the device.

A common contact may be connected to both the source region and the region having the second conductivity type. In this way, the source and the channel region of the device may be connected together. The contact may include a silicide region located at the major surface, wherein the silicide region extends over a junction between the source region and the region having the second conductivity type.

The source region, the drain region, and the region having the second conductivity type comprise doped regions located in an epitaxial layer of semiconductor material.

The first conductivity type may be n-type and the second conductivity type may be p-type. Nevertheless, it is envisaged that the first conductivity type may be p-type and the second conductivity type may be n-type.

The device may be an LDMOS (Laterally Diffused Metal Oxide Semiconductor) transistor. For instance, the LDMOS transistor may be an RF-LDMOS transistor for use in Radio Frequency applications.

For the purposes of this disclosure “Radio Frequency” (RF) refers to frequencies in the range 1 GHz≦f≦120 GHz.

In other examples, the device may be a DC LDMOS transistor. In accordance with a further aspect of this disclosure, the DC LDMOS transistor may be included in a DC biasing circuit for a circuit including an RF-LDMOS transistor. The DC biasing circuit may be used to bias the RF-LDMOS transistor during operation.

According to another aspect of this disclosure, there is provided a power amplifier comprising a semiconductor device or a circuit of the kind described above.

According to a further aspect of this disclosure, there is provided a base station comprising a power amplifier of the kind described above.

### BRIEF DESCRIPTION OF THE DRAWINGS

Embodiments of the present disclosure will be described hereinafter, by way of example only, with reference to the accompanying drawings in which like reference signs relate to like elements and in which:

FIG. 1 shows a semiconductor device comprising an RF-LDMOS transistor;

FIG. 2 shows a semiconductor device according to an embodiment of the present disclosure;

FIG. 3 is a graph showing the source to substrate breakdown of a semiconductor device according to an embodiment of the present disclosure; and

FIG. 4 is a graph showing the drain to source breakdown of a semiconductor device according to an embodiment of the present disclosure.

### DETAILED DESCRIPTION

Embodiments of the present disclosure are described in the following with reference to the accompanying drawings.

In an RF product (such as a power amplifier) including an RF-LDMOS transistor, a bias circuit may be used to bias the RF-LDMOS transistor to a DC biasing point. The bias circuit can include an LDMOS transistor. The source of the LDMOS transistor may be operated at a (DC biased) voltage above the substrate (the substrate may, for instance, be connected to ground). Such a device may be referred to as a “source-high LDMOS”. The biasing circuit including the source-high LDMOS may be incorporated into the same substrate as the RF-LDMOS transistor for which the bias point is to be provided.

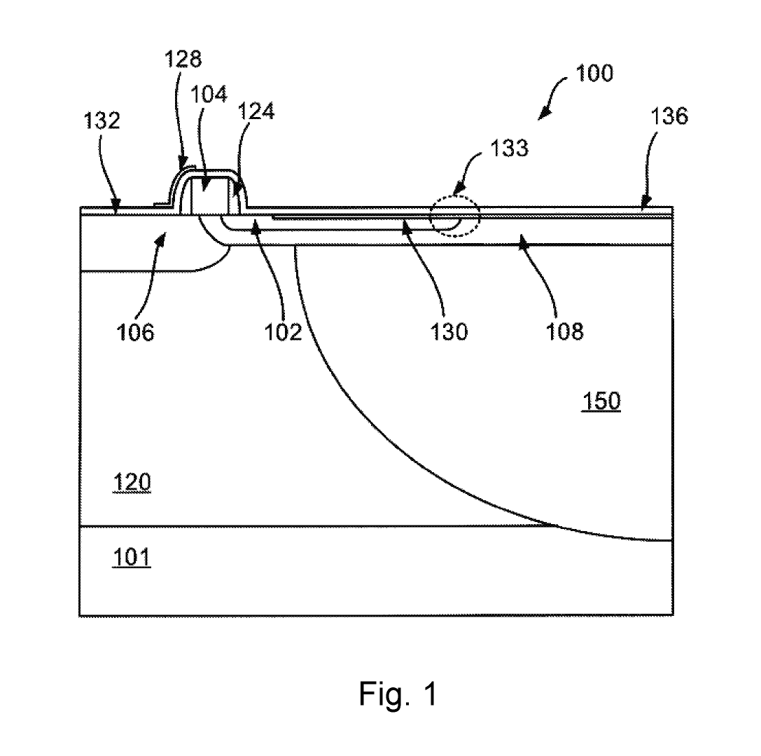

However, within a given RF-LDMOS diffusion technology, a source-high LDMOS transistor is not typically available. Apart from ESD protection devices, the only active component normally available within a given RF-LDMOS diffusion technology is the RF-LDMOS transistor. Source-high operation of such devices is not possible because RF-LDMOS devices are typically manufactured such that the source is connected to the substrate (this is explained in more detail below in relation to FIG. 1). Note that in the RF domain, connection of the source to the drain may allow the source to be connected to the flange of the transistor package, which may minimise losses (inductance) in the source connection.

Accordingly, the RF-LDMOS transistors available within a given RF-LDMOS diffusion technology are not typically suitable for use in a DC biasing circuit.

FIG. 1 shows a semiconductor device 100 comprising an RF-LDMOS transistor. The device 10 includes a semiconductor substrate 101, which includes an epitaxial layer 120 in which the various features of the RF-LDMOS transistor are provided. The substrate 101 and its epitaxial layer 120 may, for instance, comprise silicon. In this example, the substrate 101, including its epitaxial layer 120 are p-type doped. The epitaxial layer 120 may be more lightly doped than the underlying region of the substrate 101. The substrate 101 has a major surface 132.

The RF-LDMOS transistor includes a gate 104 located on the major surface 132. The gate may include a gate electrode separated from a channel region beneath the major surface 132 by a gate oxide. The gate 104 may include spacers 124.

The RF-LDMOS transistor also includes a drain region 106. The drain region 106 is located at the major surface 132 on a first side of the gate 104. The drain region 106 may form a laterally extending drain.

The RF-LDMOS transistor also includes a source region 102. The source region 102 is located at the major surface 132 on a second side of the gate 104.

A protective layer 136 of thermally grown oxide (e.g. TEOS) is provided over the major surface 132. The layer 128 is a shield that may be used to improve the reduced surface field (RESURF) behavior of the device and for reducing hot carrier injections.

In this example, the source region 102 and drain region 106 are n-type. The channel region located beneath the gate 104 comprises p-type semiconductor material. The source region 102 is located within a p-type region 108. A part of the p-type region 108 located beneath the gate 104 forms the channel region of the RF-LDMOS transistor.

As noted previously, in a RF-LDMOS transistor the source is typically connected to the substrate. In the example of FIG. 1, this connection is implemented by forming a silicide layer 130 at the major surface 132 of the substrate 101. The silicide layer 130 extends over both the source region 102 and the p-type region 108. This allows a common connection to be made to both the source region 102 and the p-type region 108, whereby the source region 102 may be connected to the substrate 101. To reduce the resistance between the source region 102 and the backside of the substrate 101 may be reduced by providing a strongly doped p-type implant 150 within the epitaxial layer 120 (which, as noted above, may be lightly doped and therefore have a relatively high electrical resistivity).

Because the source region 102 of the device 100 shown in FIG. 1 is shorted to the substrate 101 as noted above, the device 100 cannot be operated as a source high LDMOS and is therefore not suitable for use in a bias circuit for biasing the RF-LDMOS transistor of an RF product.

A possible approach to implementing a source-high RF-LDMOS transistor, based on the device 100 shown in FIG. 1 might be to remove the short between the source region 102 and the p-type region 108 formed by the silicide layer 130. For instance, this might be achieved by introducing a gap in the silicide layer 130 at the junction between the source region 102 and the p-type region 108 (the gap may be located in the region indicated using reference numeral 133 in FIG. 1). A separate connection may then be made to the silicide located on the source region 102, so that different potentials may be applied to the source region 102 and the substrate 101.

However, in an RF-LDMOS device, the diffusions and doping levels of the features of the transistor are generally optimised for RF performance. The steep doping profiles for the source region 102 and the p-type region 108 may give rise to a number of issues. For instance, the breakdown voltage between the source region 102 and the p-type region 108 may be rather low (typically 2-5 Volt depending on the processing details), in turn leading to a relatively low maximum breakdown voltage between the source region 102 and the backside of the substrate 101. Also, the device may suffer from leakage due to the silicide layer close the steep junction between the source region 102 and the p-type region 108.

Embodiments of this disclosure may provide a semiconductor device such as an LDMOS transistor which may be operated as a source high device. The device includes a drain region and a source region having a first conductivity type. A channel region of the device has a second conductivity type (i.e. a different conductivity type) to the source region and the drain region. In the examples described below, the first conductivity type is n-type and the second conductivity type is p-type (so that the source and drain regions are n-type and the channel region is p-type). However, it is envisaged that the first conductivity type may be p-type and the second conductivity type may be n-type.

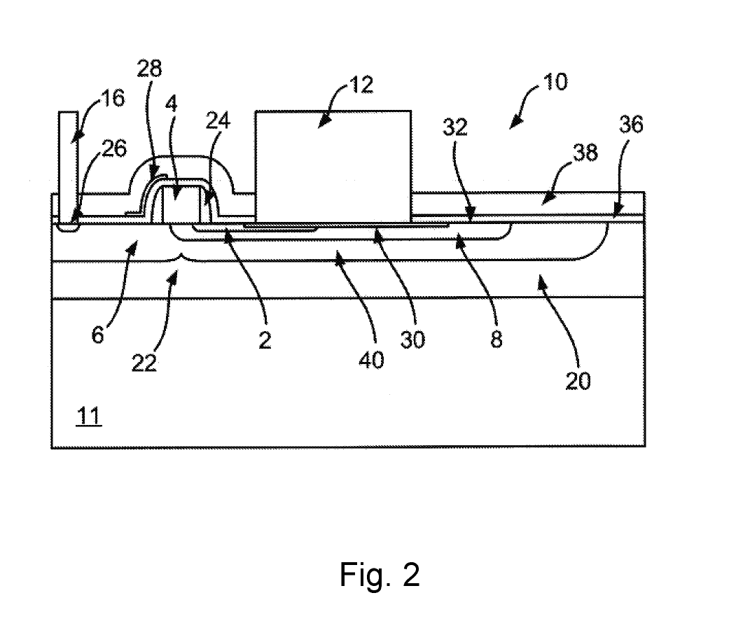

FIG. 2 shows a semiconductor device 10 according to an embodiment of the present disclosure. The device 10 in this embodiment comprises an LDMOS transistor. The device 10 includes a semiconductor substrate 11. The substrate 11 may be a silicon substrate. The substrate 11 may be doped to have the same conductivity type as a channel region of the device 11 (which in the present example is p-type). The substrate may include an epitaxial layer 20 comprising, for example, silicon. Features of the LDMOS transistor (e.g. the drain region, source region etc.) may be formed in the epitaxial layer 20. The epitaxial layer may have the same conductivity type as the substrate 11, which in this example is p-type. The epitaxial layer 20 may be more lightly doped than the underlying part of the substrate 11. The substrate 11 has a major surface 32.

The device 10 includes a gate 4 located on the major surface 32 of the substrate. The gate 4 may include a gate electrode separated from a channel region beneath the major surface 32 of the substrate by a gate insulation layer, such as an oxide layer. The gate 4 may include spacers 24.

The device 10 also includes a drain region 6. The drain region 6 is located at the major surface 32 of the substrate 11 on a first side of the gate 4. The drain region 6 may extend laterally away from the gate 4 along the major surface 32 of the substrate 11.

The LDMOS transistor also includes a source region 2. The source region 2 is located at the major surface 32 on a second side of the gate 4. Like the drain region 4, the source region may extend laterally away from the gate 4 along the major surface 32 of the substrate 11.

As noted above, in this embodiment, the source region 2 and drain region 6 are n-type. The source region 2 is located within a region 8 having the second conductivity type, which in this embodiment is p-type. As with the source region 2 and the drain region 6, the p-type region 8 may extend along the major surface 32 of the substrate 11. As shown in FIG. 2, the source region 2 may be located in between the major surface 32 and the p-type region. The p-type region 8 may extend laterally within the device 10 to a greater extent than the source region 2, so as to surround the source region 2 beneath the major surface 32. A part of the p-type region 8 extends beneath the gate 4 to form the channel region of the LDMOS transistor.

One or more protective layers 36, 38 of thermally grown oxide (e.g. TEOS) is provided over the major surface 32. The layer 28 is a shield that may be used to improve the reduced surface field (RESURF) behavior of the device and for reducing hot carrier injections.

In this embodiment, a silicide layer 30 is formed at the major surface 32 of the substrate 11 for forming a contact to the source region 2. The silicide layer 30 may extend along a top of the source region 2 at the major surface 32. The silicide layer 30 may also extend along a top of the p-type region 8 so that a common connection may be made to the source region 2 and the p-type region 8. In this way, the source region 2 and the channel region of the device 10 may be operated at the same voltage. FIG. 2 also shows the provision of an electrically conductive connection 12 extending upwardly from the silicide layer 30. The connection 12 may connect to further metallisation features provided in the device 10 for routing signals to and from the device 10. Similarly, an electrically conductive connection 16 may be provided to the drain region 6. A highly doped region 26 may be located a top the top of the drain region 6 to receive the connection 16.

FIG. 2 also shows that the drain 6 extends beneath the p-type region 8. The region of the drain 6 that extends beneath the p-type region 8 is labelled using reference numeral 40 in FIG. 2. The region 40 isolates the source region 2 and the p-type region an underlying region of the substrate 11. Since the source region 2 and the p-type region 8 are isolated from the underlying region of the substrate 11, the source region 2 may be operated at a different voltage to that applied to the backside of the substrate. Accordingly the device 10 may be operated as a source-high LDMOS transistor. Such a device may, for instance, therefore be suitable for use in a DC bias circuit in an RF product (e.g. a power amplifier) that also includes an RF-LDMOS transistor.

As shown in FIG. 2, the region 40 may surround the p-type region 8 beneath the major surface 32 so that the source region 2 and the p-type region 8 are electrically cut off from the underlying substrate.

The various features of the device 10 may be formed by ion implantation through the major surface 32 and heating of the substrate to diffuse the implanted ions. For instance, a device 10 of the kind shown in FIG. 2 may be made by providing a semiconductor substrate including an epitaxial layer and by performing ion implantation for forming the source region 2, drain region 6, p-type region 8 and the region 40.

Since the region 40 in this embodiment is an extension of the drain region 6 that extends beneath the gate 4, the drain region 6 and the region 40 may be formed using the same implant. The implantation of ions for forming the drain region 6 and the region 40 (and also other features of the device 10) may be performed after the gate 4 has been formed. Because of this, the parts of the gate 4 that are already in place when the implantation of ions for the drain region 6 and region 40 is performed may cause shadowing of the region beneath the gate 4. This may lead to a pinching of the part of the drain region 6 located beneath the gate 4. Because of this pinching effect, a part 22 of the drain region 6 located beneath the gate 4 may extend to a depth beneath the major surface 32 that is shallower than a depth to which other parts of the drain region 6 extend. As shown in FIG. 2, this part 22 may be peak shaped.

As explained below, it has been determined that the pinching of the drain region 6 beneath the gate 4 may improve the field distribution within the device, allowing for a higher maximum drain to source voltage BV_{dss} owing to an improved reduced surface field (RESURF) action in the device.

With reference to FIG. 1, the process settings for an RF-LDMOS device of this kind (e.g. doping levels, junctions depths) are optimized for the RESURF effect within the device. In the device of FIG. 1, a lateral depletion region formed at the interface between the drain region 106 and the epitaxial layer 120 beneath the gate 104 is an important part of this RESURF action. Returning to FIG. 2, because the drain region 6 extends beneath the gate, the source region 2 and the region 8 having the second conductivity type, a depletion region beneath the gate 4, of the kind mentioned above in respect of FIG. 1, may not be present. This may disturb the RESURF effect within the device 10. The part 22 of the drain region 6 located beneath the gate 4, which can give rise to a locally less deep junction between the drain region 6 (which has the first conductivity type) and the underlying epitaxial layer 20. This can cause the width of the depletion layer at the junction to be increased, which may allow the RESURF action in the device to be retained, notwithstanding the fact that the drain region 6 extends beneath the gate, the source region 2 and the region 8 having the second conductivity type.

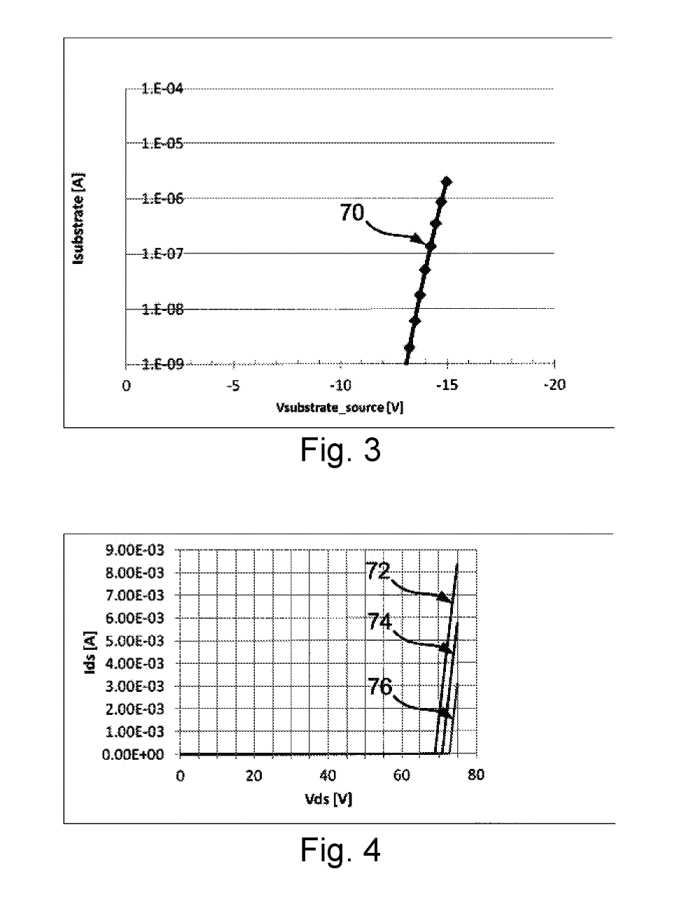

FIG. 3 is a graph showing the source to substrate breakdown of a semiconductor device according to an embodiment of the present disclosure. These measurements were made with V_{gs}=0V and V_{ds}=27V. It is believed that further optimisation of the device may make breakdown voltages up to the supply voltage (28V) possible.

FIG. 4 is a graph showing the drain to source breakdown of a semiconductor device according to an embodiment of the present disclosure. These measurements were made with V_{gs}=0V and Vₛ=0V. For plot 72, the substrate voltage was −5V. For plot 74, the substrate voltage was −2.5V. For plot 76, the substrate voltage was 0V.

Because the device 10 in FIG. 2 may be operated as a source-high LDMOS transistor, it may be used to implement a DC bias circuit in an RF product (such as a power amplifier) that includes an RF-LDMOS transistor. The device 10 may be included in the same semiconductor substrate as the RF-LDMOS transistor for which the biasing is provided, thereby to provide compensation for temperature effects.

Although the device of FIG. 2 may be used in DC mode, for instance in a biasing circuit as noted above, it is also envisaged that a device according to embodiments of the present disclosure may itself be used as an RF-LDMOS transistor.

A semiconductor device according to an embodiment of this disclosure may be used to implement a power amplifier in RF applications (e.g. either as part of a biasing circuit for biasing an RF-LDMOS transistor or as the RF-LDMOS transistor itself). For instance, the power amplifier may be included in a base station of a communication system (e.g. GSM, EDGE, W-CDMA).

Accordingly, there has been described a semiconductor device and a method of making the same. The device includes a semiconductor substrate having a major surface. the device also includes a gate located on the major surface. The device further includes a drain region having a first conductivity type. The device also includes a source region having the first conductivity type, wherein the source region is located within a region having a second conductivity type. The device further includes a channel region comprised of a part of the region having the second conductivity type that is located beneath the gate. The drain region extends laterally away from the gate along the major surface of the substrate. The drain also extends beneath the gate, the source region and the region having the second conductivity type to isolate the source region and the region having the second conductivity type from an underlying region of the substrate.

Although particular embodiments of the disclosure have been described, it will be appreciated that many modifications/additions and/or substitutions may be made within the scope of this disclosure.

What is claimed is:

1. A semiconductor device comprising:
a semiconductor substrate having a major surface;
a gate located on the major surface;
a drain region having a first conductivity type;
a source region having the first conductivity type, wherein the source region is located within a region having a second conductivity type;
a channel region comprised of a part of said region having the second conductivity type that is located beneath the gate, and
wherein the drain region extends laterally away from the gate along the major surface of the substrate and wherein the drain also extends beneath the gate, the source region and the region having the second conductivity type to isolate the source region and the region having the second conductivity type from an underlying region of the substrate.

2. The semiconductor device of claim 1, wherein a part of the drain region located beneath the gate extends to a depth beneath the major surface that is shallower than a depth to which a part of the drain not located beneath the gate extends.

3. The semiconductor device of claim 1, further comprising a common contact connected to both the source region and the region having the second conductivity type.

4. The semiconductor device of claim 3, wherein the contact comprises a silicide region located at the major surface, wherein the silicide region extends over a junction between the source region and the region having the second conductivity type.

5. The semiconductor device of claim 1, wherein the source region, the drain region, and the region having the second conductivity type comprise doped regions located in an epitaxial layer of semiconductor material.

6. The semiconductor device of claim 1, wherein the first conductivity type is n-type and wherein the second conductivity type is p-type.

7. A semiconductor device comprising a circuit, said circuit comprising an LDMOS transistor of a first type and an LDMOS of a second type that are arranged on a common substrate, said substrate having a major surface and including an epitaxial layer, both the substrate and the epitaxial layer having a second conductivity type, wherein the LDMOS transistor of the first type is configured as the semiconductor device of claim 1, wherein the drain region thereof extends beneath and laterally away from the gate along the major surface of the substrate such that it surrounds the region beneath the major surface having a second conductivity type;
wherein the LDMOS transistor of the second type comprises:
a second gate located on the major surface;
a second drain region having a first conductivity type, the second drain region forming a laterally extending drain;
a second source region having the first conductivity type, wherein the second source region is located within a second region having a second conductivity type;
a second channel region comprised of a part of said second region having the second conductivity type that is located beneath the second gate; and
a common connection to both the second source region and said second region, whereby the second source region is electrically connected to the substrate.

8. The semiconductor device of claim 7, wherein the LDMOS transistor of the second type further comprises a strongly doped implant within the epitaxial layer, said implant having the second conductivity type, said implant contacting said substrate on one side and said second region on another side.

9. The semiconductor device of claim 7, wherein the LDMOS transistor of the first type is a DC LDMOS transistor, and wherein the LDMOS transistor of the second type is an RF-LDMOS transistor, said circuit comprising a DC biasing circuit, wherein the DC biasing circuit includes the DC LDMOS transistor.

10. The semiconductor device of claim 9, wherein the biasing circuit is configured for compensating temperature effects.

11. The semiconductor device of claim 1, wherein the device is an RF-LDMOS transistor.

12. The semiconductor device of claim 1, wherein the device is a DC LDMOS transistor.

13. A circuit comprising an RF-LDMOS transistor and a DC biasing circuit, wherein the DC biasing circuit includes the semiconductor device of claim 12.

14. A power amplifier comprising the semiconductor device of claim 1.

15. A base station comprising a power amplifier according to claim 14.

16. A method of making a semiconductor device, the method comprising:
providing a semiconductor substrate having a major surface;
forming a gate on the major surface;
forming a drain region having a first conductivity type;
forming a source region having the first conductivity type, wherein the source region is located within a region having a second conductivity type, and wherein a part of said region having the second conductivity type that is located beneath the gate forms a channel region of the device, and
wherein the drain region extends laterally away from the gate along the major surface of the substrate and wherein the drain also extends beneath the gate, the source region and the region having the second conductivity type to isolate the source region and the region having the second conductivity type from an underlying region of the substrate.

17. The method of claim 16, comprising:
implanting ions through the major surface of the substrate for forming the drain region; and
heating the substrate to diffuse the implanted ions to form the drain region, wherein the drain region extends beneath the gate, the source region and the region having the second conductivity type.

18. The method of claim 17, wherein during said implantation of ions for forming the drain region, the gate shadows a part of the device located beneath the gate whereby a part of the drain region located beneath the gate extends to a depth beneath the major surface that is shallower than a depth to which a part of the drain not located beneath the gate extends.

19. The method of claim 16, wherein the first conductivity type is n-type and wherein the second conductivity type is p-type.

20. A power amplifier comprising the circuit of claim 13.
